(19) United States
(12) Patent Application Publication
(10) Pub. No.: US 2008/0132081 A1
(43) Pub. Date: Jun. 5, 2008

(54) Thin III-V semiconductor films with high electron mobility

(76) Inventors: Mohamad A. Shaheen, Portland, OR (US); Mantu K. Hudait, Portland, OR (US); Willy Rachmady, Beaverton, OR (US); Jack T. Kavalieros, Portland, OR (US); Chris E. Barns, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/633,953

(22) Filed: Dec. 4, 2006

(51) Int. Cl. H01L 21/00

(52) U.S. Cl. 438/759

(57) ABSTRACT

A method of forming a thin III-V semiconductor film on a semiconductor substrate, where the lattice structure of the III-V film is different than the lattice structure of the substrate. The method includes epitaxially growing the III-V film on the substrate until the III-V film is greater than 3.0 μm thick and then removing a portion of the III-V film until it is less than 3.0 μm thick. In one implementation, the III-V film is grown until it is around 8.0 μm to 10.0 μm thick, and then it is etched or polished until its thickness is reduced to 0.1 μm to 3.0 μm thick. By over-growing the III-V film, effects such as dislocation gliding and annihilation reduce the dislocation density of the film, thereby improving its electric mobility.

### BACKGROUND

In the manufacture of integrated circuits, materials other than silicon and germanium may be used to form a semiconductor substrate. For instance, III-V semiconductor materials may be used, which are synthesized using elements from the 3rd and the 5th group of the periodic table. Examples of III-V semiconductor materials include gallium arsenide (GaAs), gallium phosphide (GaP), gallium nitride (GaN), gallium aluminum arsenide (GaAIAs), indium phosphide (InP), indium arsenide (InAs), and indium antimonide (InSb).

When a thin III-V film is epitaxially grown on a substrate having a different lattice structure, the lattice mismatch generally causes a high dislocation density in the III-V film. For instance, heteroepitaxially grown III-V films can have a dislocation density that ranges from 1×10⁶/cm² to 1×10¹⁰/cm² to accommodate a lattice mismatch of a few percent up to around 20%. This high dislocation density greatly reduces the electrical mobility of the thin III-V film relative to that of a thick, dislocation-free III-V film. This dislocation issue prevents the fabrication of relatively thin III-V films that are suitable for use in integrated circuit devices.

### BRIEF DESCRIPTION OF THE DRAWINGS

FIG. 1 is a method of forming a thin III-V film in accordance with an implementation of the invention.

FIGS. 2A to 2D illustrate the method described in FIG. 1.

### DETAILED DESCRIPTION

Described herein are systems and methods of forming a thin III-V semiconductor film on a lattice-mismatched substrate that has high electrical mobility. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As is known in the art, when a thin III-V semiconductor film is grown on a lattice mismatched substrate (i.e., the lattice structure of the film is different than the lattice structure of the substrate), the lattice mismatch causes a high number of dislocations to form in the film. This results in a high dislocation density for the thin III-V film, decreasing its electric mobility (i.e., electron or hole mobility) relative to a thick, dislocation-free III-V film.

For instance, a substantially dislocation-free InSb film that is grown on a GaAs substrate to a thickness of 8 micrometers (μm) to 10 μm may have an electric mobility that ranges from 70,000 square centimeters per volt-second (cm²/V-s) to 74,000 cm²/V-s. If, however, the InSb film is grown to a thickness of less than 3 μm, its electric mobility drops to less than 30,000 cm²/V-s due to the high dislocation density. It is known that electric mobility depends at least in part on film thickness. That is why generally, to obtain the highest electric mobility, thick III-V films on the order of 8 μm to 10 μm are grown. Unfortunately, these thick films require very long growth times and are not practical for integrated circuit device applications.

Accordingly, implementations of the invention provide a method to form high-mobility III-V semiconductor films that are relatively thin despite being epitaxially grown on a lattice mismatched substrate. Such III-V films may then be used in integrated circuit devices such as quantum wells devices.

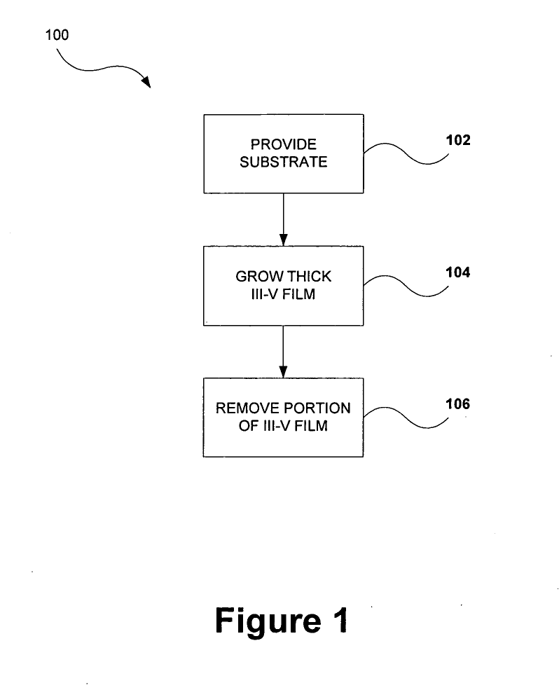

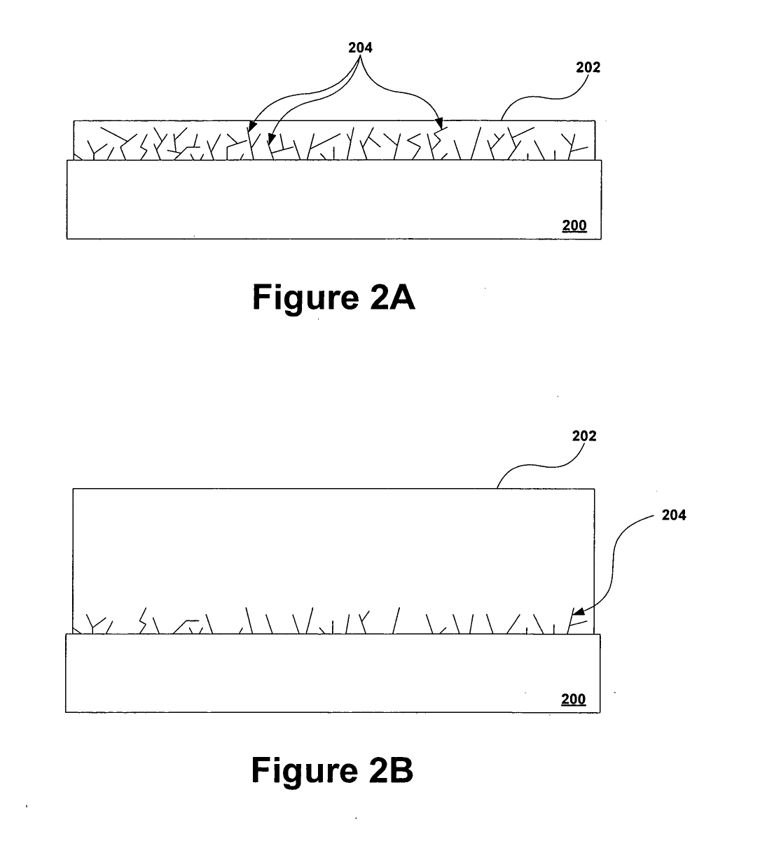

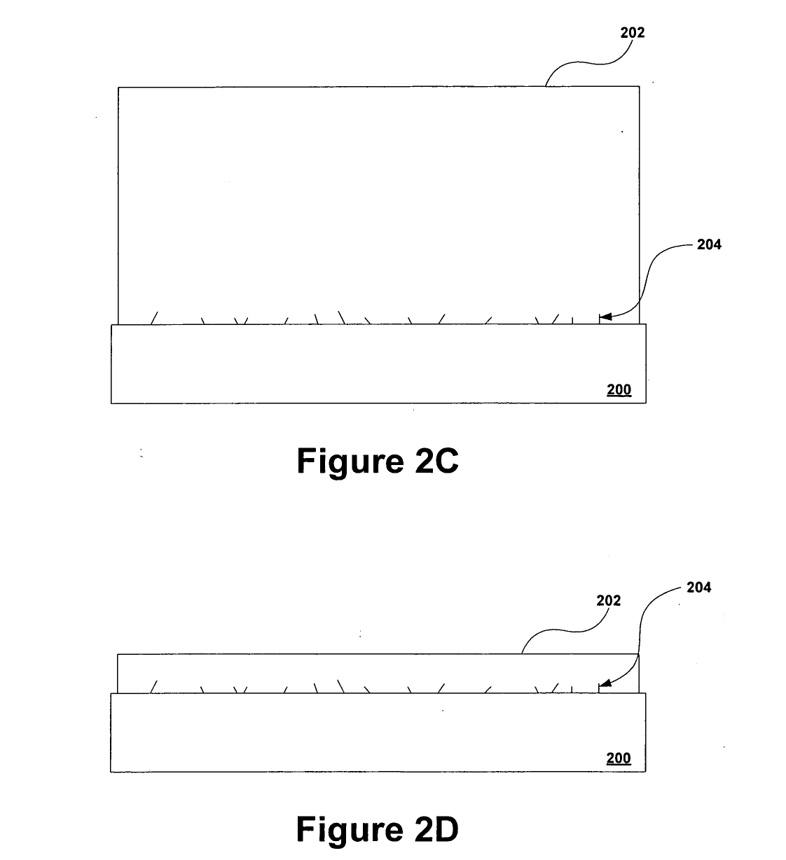

FIG. 1 is a method 100 of forming a thin III-V film on a lattice mismatched substrate in accordance with an implementation of the invention. The thin III-V film has a relatively low dislocation density despite being epitaxially grown on a substrate having a different lattice structure than the III-V film. FIGS. 2A through 2D illustrate structures that are formed when the method of FIG. 1 is carried out.

The method 100 begins by providing a substrate upon which the III-V film will be grown (102 of FIG. 1). The substrate is generally a semiconductor substrate and may be formed from known semiconductor materials. For instance, in some implementations the substrate may be formed from a III-V material such as gallium arsenide (GaAs), gallium phosphide (GaP), gallium nitride (GaN), gallium aluminum arsenide (GaAIAs), indium phosphide (InP), indium arsenide (InAs), and indium antimonide (InSb). In further implementations, other semiconductor materials may be used for the substrate, such as silicon-containing materials, germanium-containing materials, or other group IV containing materials. The substrate used has a first lattice structure.

Next, a relatively thick III-V film is epitaxially grown on the substrate (104). The thickness of the thick III-V film is greater than 3 μm, and generally ranges from around 8 μm to around 10 μm thick. The thick III-V film is formed from a III-V semiconductor material including, but not limited to, GaAs, GaP, GaN, GoAIAs, InP, and InSb. In implementations of the invention, the thick III-V film has a second lattice structure that is different than the first lattice structure of the substrate.

Several different epitaxial processes may be employed to grow the thick III-V film on the lattice mismatched substrate. In some implementations, the epitaxial film growth may be carried out using a molecular beam epitaxy (MBE) process, a metalorganic chemical vapor deposition (MOCVD) process, a metalorganic vapor phase epitaxy (MOVPE) process, or a pulsed laser deposition (PLD) process. Alternate epitaxial methods may also be employed, as will be appreciated by those of ordinary skill in the art.

As the thickness of the III-V film increases, its dislocation density decreases due to factors such as dislocation gliding and annihilation during growth either due to temperature or to over-growth mechanisms. The dislocation annihilation occurs throughout the entire III-V film and is not limited to a top portion of the film. Accordingly, as the thickness of the III-V film increases, the electric mobility of the III-V film increases as well. For example, when the thickness of the III-V film increases to around 8 μm, the electric mobility of the III-V film increases to a near bulk-like value. For this reason a thick (e.g., around 8 μm to 10 μm) III-V film is grown to fully glide a substantial number of the dislocations.

FIGS. 2A through 2C illustrate the growth of the thick III-V film. FIG. 2A illustrates a III-V film 202 that has just started to grow on a semiconductor substrate 200. As described above, the substrate 200 may be formed from one or a combination of group III materials, group IV materials, and group V materials. The thickness of the III-V film 202 in FIG. 2A may range from 0.1 μm to 3.0 μm. Initially, the III-V film 202 has a high number of dislocations 204 due to the lattice structure of the III-V film 202 being different than the lattice structure of the substrate 200.

FIG. 2B illustrates the III-V film 202 after it has undergone further epitaxial growth. For example, the thickness of the III-V film 202 in FIG. 2B may range from 3.0 μm to 7.9 μm. The number of dislocations 204 has decreased due to effects such as dislocation gliding and annihilation.

FIG. 2C illustrates the final thick III-V film 202 after the epitaxial growth process is complete. Here, the thickness of the III-V film 202 in FIG. 2C may range from 8.0 μm to 10.0 μm. The number of dislocations 204 has further decreased due to further dislocation gliding and annihilation and is significantly less than the initial film shown in FIG. 2A. As a result, the III-V film 202 now exhibits near bulk-like mobility.

After the thick III-V film has been grown, a thinning process is carried out to remove a portion of the III-V film and reduce its thickness down to a desired final thickness (106). In some implementations of the invention, the thinning process removes a substantial portion of the III-V film and reduces its thickness down to the 0.1 μm to 3 μm level. The result is a thin III-V film on the substrate that has a low dislocation density.

The thinning process can consist of a wet etch process, a dry etch process, or a chemical mechanical planarization process. In some implementations a combination of two or more of the above processes may be used. In an implementation where a chemical mechanical planarization process is used, a Cu10k commercial slurry, which may be obtained from Planar Solutions of Adrian, Mich., may be used without peroxide. In an implementation where a wet etch process is used, the wet etch chemistry may include a combination of two or more of the following chemicals: lactic acid, nitric acid, hydrofluoric acid, and ammonium fluoride.

When the thick III-V film is thinned down, the thinned III-V film retains the high mobility characteristics of the thick film, thereby exhibiting a hysteresis-like behavior. Due to this phenomenon, implementations of the invention can fabricate thin, high-mobility III-V films grown on lattice mismatched substrates that are otherwise unattainable.

FIG. 2D illustrates the III-V film 202 after the thinning process has removed a significant portion of the film and reduced its thickness down to a final, desired thickness. For example, the thickness of the III-V film 202 in FIG. 2D may now range from 0.1 μm to 3.0 μm. Due to the hysteresis-like behavior of the III-V film 202, the number of dislocations 204 remain substantially unchanged from the number of dislocations in the thick III-V film 202 shown in FIG. 2C. As such, a thin III-V film 202 has been fabricated having a high electric mobility.

In a further implementation of the invention, an annealing process may be applied during the growth of the thick III-V film or after the thinning process is carried out. In another implementation, the anneal can take place both during growth of the thick III-V film and after thinning of the film. The application of an anneal tends to improve gliding of the dislocations. The anneal may take place at one or more temperatures between around 400° C. and 800° C. for a time duration that can range from 15 minutes to 5 hours, depending on the III-V material used. Lower temperatures and shorter durations may be used for lower bandgap materials such as InAs or InSb.

To illustrate the advantages provided by implementations of the invention, consider a thin (i.e., less than 3.0 μm) InSb film formed on a GaAs substrate using a conventional growth method compared to one formed in accordance with an implementation of the invention that is grown thick and then thinned back. The conventionally formed InSb film has a lattice mismatch of around 15%, which severely affects its electric mobility. In fact, such a conventionally formed InSb exhibits an electric mobility that is less than 30,000 cm²/V-s. Contrary to this, a thin InSb film formed in accordance with an implementation of the invention has an electric mobility that is greater than 60,000 cm²/V-s. As such, a thin InSb film formed in accordance with an implementation of the invention demonstrates an improvement that is over two times better than conventionally grown films. Of course, this improvement is not limited to InSb on GaAs. Any of the III-V materials described above on any of the substrates described above will demonstrate an improvement in electric mobility. Generally, implementations of the invention have shown reductions in dislocation density in thin III-V films by two to three orders of magnitude.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
growing a III-V film on a substrate until the III-V film reaches a first thickness; and
removing a portion of the III-V film until the III-V material reaches a second thickness.

2. The method of claim 1, wherein the III-V film has a first lattice structure and the substrate has a second lattice structure, and wherein the first lattice structure is different than the second lattice structure.

3. The method of claim 1, wherein the III-V film comprises gallium arsenide, gallium phosphide, gallium nitride, gallium aluminum arsenide, indium phosphide, indium arsenide, or indium antimonide.

4. The method of claim 1, wherein the substrate comprises silicon, germanium, gallium arsenide, gallium phosphide, gallium nitride, gallium aluminum arsenide, indium phosphide, indium arsenide, or indium antimonide.

5. The method of claim 1, wherein the first thickness ranges from 3.0 μm to 10.0 μm.

6. The method of claim 1, wherein the second thickness ranges from 0.1 μm to 3.0 μm.

7. The method of claim 1, wherein the growing of the III-V film is carried out using a molecular beam epitaxy process, a metalorganic chemical vapor deposition process, a metalorganic vapor phase epitaxy process, or a pulsed laser deposition process.

8. The method of claim 1, wherein the removing of the portion of the III-V film is carried out using a wet etch process, a dry etch process, or a chemical mechanical polishing process.

9. The method of claim 1, further comprising annealing the III-V film during the growing of the III-V film.

10. The method of claim 1, further comprising annealing the III-V film after the removing of the portion of the III-V film.

11. A method comprising:
epitaxially growing a III-V film on a semiconductor substrate until the III-V film is greater than 3.0 μm thick, wherein the III-V film has a first lattice structure and the semiconductor substrate has a second lattice structure that is different than the first lattice structure; and
polishing the III-V film until the III-V film is less than 3.0 μm thick.

12. The method of claim 11, wherein the III-V film comprises gallium arsenide, gallium phosphide, gallium nitride, gallium aluminum arsenide, indium phosphide, indium arsenide, or indium antimonide.

13. The method of claim 11, wherein the substrate comprises silicon, germanium, gallium arsenide, gallium phosphide, gallium nitride, gallium aluminum arsenide, indium phosphide, indium arsenide, or indium antimonide.

14. The method of claim 11, wherein the epitaxial growing of the III-V film is carried out using a molecular beam epitaxy process, a metalorganic chemical vapor deposition process, a metalorganic vapor phase epitaxy process, or a pulsed laser deposition process.

15. The method of claim 11, wherein the polishing of the III-V film is carried out using a chemical mechanical polishing process.

16. The method of claim 11, further comprising annealing the III-V film during the epitaxial growing of the III-V film.

17. The method of claim 11, further comprising annealing the III-V film after the polishing of the III-V film.

18. A method comprising:
epitaxially growing a III-V film on a semiconductor substrate until the III-V film is greater than 3.0 μm thick, wherein the III-V film has a first lattice structure and the semiconductor substrate has a second lattice structure that is different than the first lattice structure; and
etching the III-V film until the III-V film is less than 3.0 μm thick.

19. The method of claim 18, wherein the III-V film comprises gallium arsenide, gallium phosphide, gallium nitride, gallium aluminum arsenide, indium phosphide, indium arsenide, or indium antimonide.

20. The method of claim 18, wherein the substrate comprises silicon, germanium, gallium arsenide, gallium phosphide, gallium nitride, gallium aluminum arsenide, indium phosphide, indium arsenide, or indium antimonide.

21. The method of claim 18, wherein the epitaxial growing of the III-V film is carried out using a molecular beam epitaxy process, a metalorganic chemical vapor deposition process, a metalorganic vapor phase epitaxy process, or a pulsed laser deposition process.

22. The method of claim 18, wherein the etching of the III-V film is carried out using a wet etch process or a dry etch process.

23. The method of claim 18, further comprising annealing the III-V film during the epitaxial growing of the III-V film.

24. The method of claim 18, further comprising annealing the III-V film after the etching of the III-V film.
